(19) United States
(12) Patent Application Publication
(10) Pub. No.: US 2015/0099332 A1
(43) Pub. Date: Apr. 9, 2015

(54) RESIN COMPOSITION, SUBSTRATE AND METHOD OF MANUFACTURING ELECTRONIC DEVICE

(71) Applicants: AKRON POLYMER SYSTEMS INC., Akron, OH (US); SUMITOMO BAKELITE COMPANY LIMITED, Shinagawa-ku (JP)

(72) Inventors: Limin SUN, Copley, OH (US); Dong ZHANG, Uniontown, OH (US); Jiaokai JING, Uniontown, OH (US); Frank W. HARRIS, Boca Raton, FL (US); Hideo UMEDA, Kobe City (JP); Toshihiko KATAYAMA, Kobe City (JP); Jun OKADA, Kobe City (JP); Mizuho INOUE, Kobe City (JP); Manabu NAITO, Kobe City (JP)

(73) Assignees: AKRON POLYMER SYSTEMS INC., Akron, OH (US); SUMITOMO BAKELITE COMPANY LIMITED, Shinagawa-ku (JP)

(21) Appl. No.: 14/506,040

(22) Filed: Oct. 3, 2014

Related U.S. Application Data
(60) Provisional application No. 61/887,048, filed on Oct. 4, 2013.

(51) Int. Cl. C08L 77/06; H01L 51/52; H01L 51/44; H01L 51/56

(52) U.S. Cl. CPC C08L 77/06; H01L 51/56; H01L 51/5253; H01L 51/448
USPC 438/127; 524/607; 428/474.4; 428/335

(57) ABSTRACT

Provided are a resin composition and a substrate that are capable of being used for producing an electronic device including thin-film transistors having an excellent switching property. The resin composition contains an aromatic polyamide and a solvent dissolving the aromatic polyamide. The resin composition is used to form a layer, and a total light transmittance of the layer in a wavelength of 355 nm is 10% or less. Further, a method of manufacturing the electronic device using such a substrate is also provided.

### CROSS-REFERENCE TO RELATED APPLICATIONS

The present application is based upon and claims the benefit of priority to U.S. Application No. 61/887,048, filed Oct. 4, 2013, the entire contents of which are incorporated herein by reference.

### TECHNICAL FIELD

The present invention relates to a resin composition, a substrate and a method of manufacturing an electronic device.

### BACKGROUND ART

In a display device (electronic device) such as an organic EL (electroluminescence) display device and a liquid crystal display device, transparency is required in a substrate used in the display device. Therefore, it is known to use a transparent resin film as the substrate used in the display device (for example, the patent document 1).

The transparent resin film used as the substrate generally has flexibility (flexible characteristics). Therefore, the transparent resin film is first formed (film-formed) on a first surface of a plate-like base member and then each element to be provided in the display device is formed on the transparent resin film. Finally, by peeling off the transparent resin film from the base member, it is possible to manufacture the display device including the transparent resin film and the elements.

In the method of manufacturing such a display device, the peeling-off of the transparent resin film from the base member is achieved by irradiating a second surface of the base member opposite to the first surface on which the transparent resin film is formed with light such as laser light. The irradiation of the light results in the peeling-off of the transparent resin film from the base member in an interface between the base member and the transparent resin film.

Meanwhile, in recent years, a display device having thin-film transistors (TFT) is used. The thin-film transistors (TFT) serve as switching elements which can switch display elements included in the display device.

Each of the thin-film transistors has, for example, an oxide semiconductor layer in a channel region. If the method of manufacturing the display device as described above is used for manufacturing the display device having the thin-film transistors, the oxide semiconductor layer of each thin-film transistor is exposed to the light. In particular, in the case where the light used in the above method includes a short wavelength, an oxide semiconductor material contained in the oxide semiconductor layer is altered and deteriorated due to the light having the short wavelength, so that a problem in that adverse effects are given to a switching property of the display device occurs.

The patent document 1: WO 2004/039863

### SUMMARY OF THE INVENTION

It is an object of the present invention to provide a resin composition and a substrate that are capable of being used for manufacturing an electronic device including thin-film transistors having an excellent switching property. It is another object of the present invention to provide a method of manufacturing the electronic device using such a substrate.

In order to achieve the objects described above, the present invention includes the following features (1) to (14).

(1) A resin composition comprising:

an aromatic polyamide; and

a solvent dissolving the aromatic polyamide,

wherein the resin composition is used to form a layer, and a total light transmittance of the layer in a wavelength of 355 nm is 10% or less.

(2) In the above resin composition according to the present invention, it is preferred that the aromatic polyamide contains a naphthalene structure.

(3) In the above resin composition according to the present invention, it is also preferred that the aromatic polyamide contains a carboxyl group.

(4) In the above resin composition according to the present invention, it is also preferred that the aromatic polyamide is a wholly aromatic polyamide.

(5) In the above resin composition according to the present invention, it is also preferred that the aromatic polyamide has a first repeating unit represented by the following general formula (I) and a second repeating unit represented by the following general formula (II):

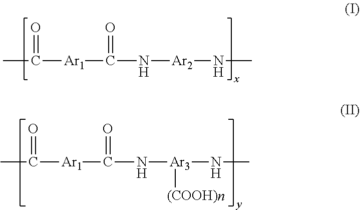

where x represents mol % of the first repeating unit, y represents mol % of the second repeating unit, n represents an integer of 1 to 4, Ar₁ is represented by the following general formula (III);

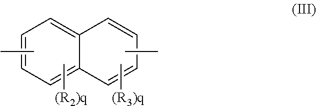

(where q=3 and each of R₂ and R₃ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them), Ar₂ is represented by the following general formula (IV) or (V);

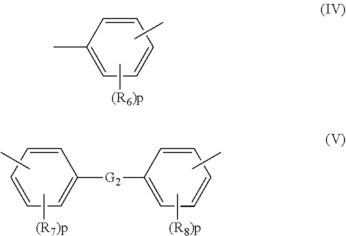

(where p=4, each of R₆, R₇ and R₈ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them, and G₂ is selected from the group consisting of a covalent binding, a CH₂ group, a C(CH₃)₂ group, a C(CF₃)₂ group, a C(CX₃)₂ group (X represents a halogen atom), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.)), and Ar₃ is represented by the following general formula (VI) or (VII);

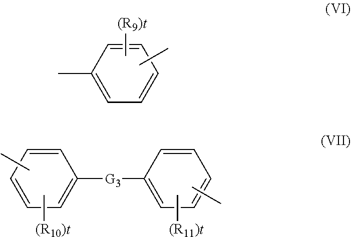

(where t=1 to 3, each of R₉, R₁₀ and R₁₁ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them, and G₃ is selected from the group consisting of a covalent binding, a CH₂ group, a C(CH₃)₂ group, a C(CF₃)₂ group, a C(CX₃)₂ group (X represents a halogen atom), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.)).

(6) In the above resin composition according to the present invention, it is also preferred at least one end of the aromatic polyamide is end-capped.

(7) In the above resin composition according to the present invention, it is also preferred that the resin composition further contains an inorganic filler.

(8) A substrate used for forming an electronic element thereon, comprising:

a plate-like base member having a first surface and a second surface opposite to the first surface;

an electronic element formation layer provided at a side of the first surface of the base member and configured to be capable of forming the electronic element on the electronic element formation layer; and

wherein the electronic element formation layer contains an aromatic polyamide and a total light transmittance of the electronic element formation layer in a wavelength of 355 nm is 10% or less.

(9) In the above substrate according to the present invention, it is preferred that a coefficient of thermal expansion (CTE) of the electronic element formation layer is 100 ppm/K or less.

(10) In the above substrate according to the present invention, it is also preferred that an average thickness of the electronic element formation layer is in the range of 1 to 50 μm.

(11) A method of manufacturing an electronic device, comprising:

preparing a substrate, the substrate including,
a plate-like base member having a first surface and a second surface opposite to the first surface, and
an electronic element formation layer provided at a side of the first surface of the base member,
wherein the electronic element formation layer is used to form an electronic element on the electronic element formation layer and contains an aromatic polyamide, and
wherein a total light transmittance of the electronic element formation layer in a wavelength of 355 nm is 10% or less;

forming the electronic element on a surface of the electronic element formation layer opposite to the base member;

forming a cover layer so as to cover the electronic element;

irradiating the electronic element formation layer with light to thereby peel off the electronic element formation layer from the base member in an interface between the base member and the electronic element formation layer; and

separating the electronic device including the electronic element, the cover layer and the electronic element formation layer from the base member.

(12) In the above method of manufacturing the electronic device according to the present invention, it is preferred that a coefficient of thermal expansion (CTE) of the electronic element formation layer is 100 ppm/K or less.

(13) In the above method of manufacturing the electronic device according to the present invention, it is also preferred that an average thickness of the electronic element formation layer is in the range of 1 to 50 μm.

(14) In the above method of manufacturing the electronic device according to the present invention, it is also preferred that the aromatic polyamide has a first repeating unit represented by the following general formula (I) and a second repeating unit represented by the following general formula (II):

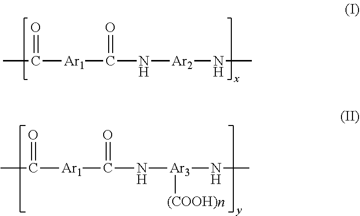

where x represents mol % of the first repeating unit, y represents mol % of the second repeating unit, n represents an integer of 1 to 4, Ar₁ is represented by the following general formula (III);

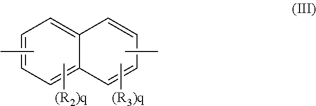

(where q=3 and each of R₂ and R₃ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them), Ar₂ is represented by the following general formula (IV) or (v);

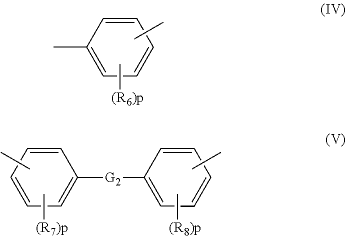

(where p=4, each of R₆, R₇ and R₈ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them, and G₂ is selected from the group consisting of a covalent binding, a CH₂ group, a C(CH₃)₂ group, a C(CF₃)₂ group, a C(CX₃)₂ group (X represents a halogen atom), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.)), and Ar₃ is represented by the following general formula (VI) or (VII);

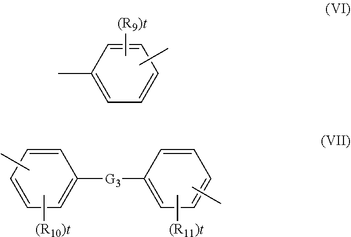

(where t=1 to 3, each of R₉, R₁₀ and R₁₁ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group and a combination of them, and G₃ is selected from the group consisting of a covalent binding, a CH₂ group, a C(CH₃)₂ group, a C(CF₃)₂ group, a C(CX₃)₂ group (X represents a halogen atom), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.)).

According to the present invention, it is possible to form a layer by using the resin composition containing the aromatic polyamide and the solvent dissolving the aromatic polyamide, wherein the total light transmittance of such a layer in the wavelength of 355 nm is 10% or less. This layer formed by using the resin composition is used as the electronic element, formation layer provided in the electronic device. The electronic element formation layer is provided on a first surface (one surface) of the base member so as to contact with the base member. Further, by irradiating a second surface of the base member opposite to the first surface on which the electronic element formation layer is provided with light having a short wavelength such as laser light, it is possible to peel off the electronic element formation layer from the first surface of the base member. By using the layer formed of the resin composition of the present invention as the electronic element formation layer, it is possible to reliably suppress or prevent the light irradiated from a side of a surface of the electronic element formation layer contacting with the base member from transmitting from the surface to an opposite surface of the electronic element formation layer through the electronic element formation layer. Therefore, it is possible to reliably prevent a switching property of the display device from being adversely affected by the irradiation of the light to the thin-film transistors included in the electronic device.

### BRIEF DESCRIPTION OF THE DRAWINGS

FIG. 1 is a vertical sectional view which shows an embodiment of an organic electroluminescence display device manufactured by applying a method of manufacturing an electronic device of the present invention as a method of manufacturing the organic electroluminescence display device.

FIG. 2 is a sectional view which shows an embodiment of a sensor element manufactured by applying the method of manufacturing the electronic device of the present invention.

FIG. 3 is a vertical sectional view to illustrate the method of manufacturing the organic electroluminescence display device shown in FIG. 1 or the sensor element shown in FIG. 2 (method of manufacturing the electronic device of the present invention).

### MODE FOR CARRYING OUT THE INVENTION

Hereinafter, a resin composition, a substrate and a method of manufacturing an electronic device according to the present invention will be described in detail based on the preferred embodiments shown in the accompanying drawings.

First, prior to describing the resin composition, the substrate and the method of manufacturing the electronic device according to the present invention, description will be made on an organic electroluminescence display device (organic EL display device) and a sensor element, which are manufactured by using the method of manufacturing the electronic device of the present invention. Namely, the organic electroluminescence display device and the sensor element will be first described as examples of the electronic device of the present invention.

<Organic EL Display Device>

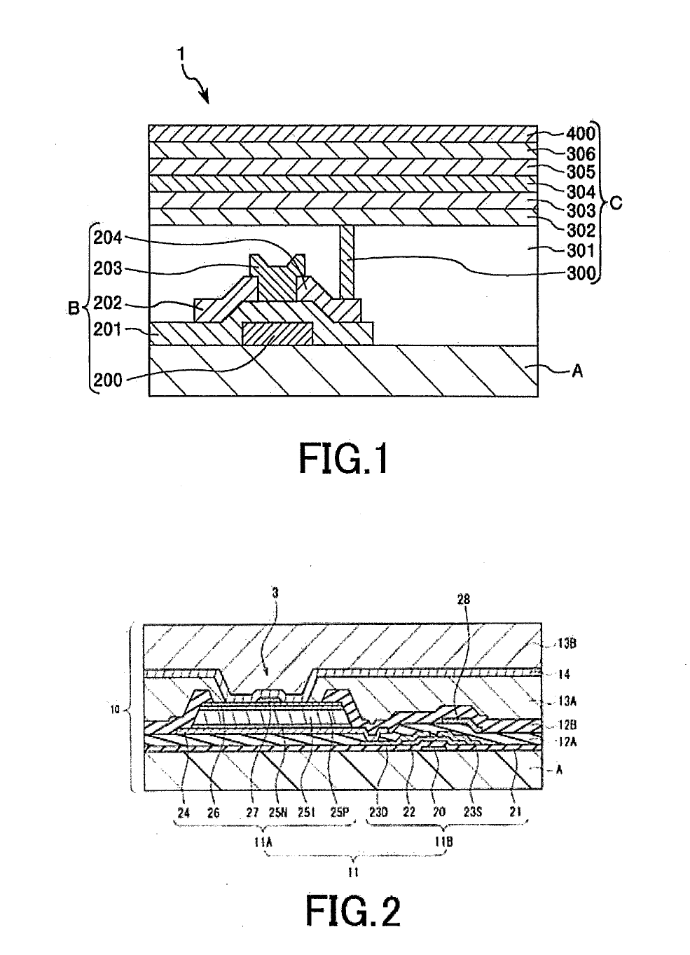

First, the organic electroluminescence display device manufactured by applying the method of manufacturing the electronic device of the present invention will be described. FIG. 1 is a vertical sectional view which shows an embodiment of the organic electroluminescence display device manufactured by applying the method of manufacturing the electronic device of the present invention as a method of manufacturing the organic electroluminescence display device. In the following description, the upper side in FIG. 1 will be referred to as “upper”, and the lower side in FIG. 1 will be referred to as “lower”.

An organic EL display device 1 shown in FIG. 1 includes a resin film (electronic element formation layer) A formed of the resin composition of the present invention, light emitting devices C each provided so as to correspond to each pixel, and a plurality of thin-film transistors B for respectively driving the light emitting devices C. Hereinafter, the organic EL display device 1 will be described with reference to FIG. 1.

In this regard, it is to be noted that, in the present embodiment, the organic EL display device 1 is a display panel of a bottom emission type. When the light emitting devices C emit light, the display panel of the bottom emission type can allow the emitted light to transmit through the resin film A to a lower side in FIG. 1 and be extracted from the lower side of the organic EL display device 1.

The thin-film transistors B are provided on the resin film (electronic element formation layer) A so as to correspond to the plurality of light emitting devices C included in the organic EL display device 1. A planarizing layer 301 constituted of an insulating material is formed on the resin film A so as to cover each thin-film transistor B.

Each of the thin-film transistors B includes a gate electrode 200 formed on the resin film A, a gate insulating layer 201 formed so as to cover the gate electrode 200, a source electrode 202 and a drain electrode 204 which are provided on the gate insulating layer 201, and a semiconductor layer 203 constituted of an oxide semiconductor material and formed in a channel region between the source electrode 202 and the drain electrode 204.

Examples of the oxide semiconductor material include a material which includes: at least an oxygen atom (O) as a non-metal element including a nitrogen atom (N) and the oxygen atom (O); at least one of a boron atom (B), a silicon atom (Si), a germanium atom (Ge), an arsenic atom (As), an antimony atom (Sb), a tellurium atom (Te) and a polonium atom (Po) as a metalloid element; and at least one of an aluminum atom (Al), a zinc atom (Zn), a gallium atom (Ga), a cadmium atom (Cd), an indium atom (In), a tin atom (Sn), a mercury atom (Hg), a thallium atom (Tl), a terbium atom (Tb) and a bismuth atom (Bi) as a metal element. In this regard, it is preferred that the non-metal element is a mixture containing the oxygen atom (O) and the nitrogen atom (N). Further, it is preferred that the oxide semiconductor material contains the indium atom (In), the tin atom (Sn), the silicon atom (Si), the oxygen atom (O) and the nitrogen atom (N) as a main component thereof.

Concrete examples of such an oxide semiconductor material include a material obtained by combining a metal raw material (In₂O₃, SnO₂) with an insulating raw material (Si₃N₄).

Further, the light emitting devices (organic EL devices) C are provided on the planarizing layer 301 so as to respectively correspond to the thin-film transistors B.

In this embodiment, each of the light emitting devices C includes an anode 302 and a cathode 306, and further includes a hole transport layer 303, an emission layer 304 and an electron transport layer 305 which are laminated in this order from the anode 302 between the anode 302 and the cathode 306.

Furthermore, the anode 302 of each light emitting device C is electrically connected to the drain electrode 204 of each corresponding thin-film transistor B through a conductive part 300.

In the organic EL display device 1 including the plurality of light emitting devices C having such a configuration, luminescence brightness of each light emitting device C can be controlled by using each corresponding thin-film transistor B. That is, by controlling a voltage to be applied to each light emitting device C, it is possible to control the luminescence brightness of each light emitting device C. By controlling the luminescence brightness of each light emitting device C, it becomes possible for the organic EL display device 1 to perform a full color display. Further, it is also possible for the organic EL display device 1 to perform a mono color display by synchronously emitting the light from the light emitting devices C at the same time.

Furthermore, in this embodiment, a sealing substrate 400 is formed on each light emitting device C so as to cover it. This makes it possible to ensure airtightness of the light emitting devices C, thereby enabling to prevent oxygen or moisture from penetrating into the light emitting devices C.

<Sensor Element>

Next, the sensor element manufactured by applying the method of manufacturing the electronic device of the present invention will be described. FIG. 2 is a sectional view which shows an embodiment of the sensor element manufactured by applying the method of manufacturing the electronic device of the present invention. In the following description, the upper side in FIG. 2 will be referred to as “upper”, and the lower side in FIG. 2 will be referred to as “lower”.

The sensor element of the present invention is, for example, a sensor element that can be used in an input device. In one or plurality of embodiments of this discloser, the sensor element of the present invention is a sensor element including the resin film (electronic element formation layer) A formed of the resin composition of the present. In one or plurality of embodiments of this discloser, the sensor element of the present invention is a sensor element formed on the resin film A on the base member 500. In one or plurality of embodiments of this discloser, the sensor element of the present invention is a sensor element that can be peeled off from the base member 500.

Examples of the sensor element of the present invention includes an optical sensor element for capturing an image, an electromagnetic sensor element for sensing an electromagnetic wave, a radiation sensor element for sensing radiation such as X-rays, a magnetic sensor element for sensing a magnetic field, a capacitive sensor element for sensing a change of capacitance charge, a pressure sensor element for sensing a change of pressure, a touch sensor element and a piezoelectric sensor element.

Examples of the input device using the sensor element of the present invention includes a radiation (X-rays) imaging device using the radiation (X-rays) sensor element, a visible-light imaging device using the optical sensor element, a magnetic sensing device using the magnetic sensor element, a touch panel using the touch sensor element or the pressure sensor element, a finger authenticating device using the optical sensor element and a light emitting device using the piezoelectric sensor. The input device using the sensor element of the present invention may further have a function of an output device such as a displaying function and the like.

Hereinafter, an optical sensor element including a photodiode will be described as one example of the sensor element of the present invention.

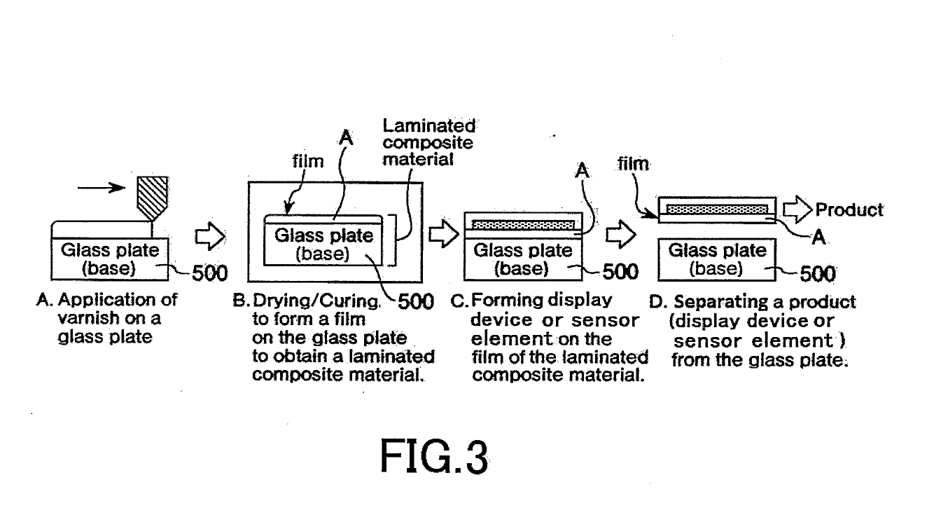

A sensor element 10 shown in FIG. 3 includes the resin film (electronic element formation layer) A formed of the resin composition of the present invention and a plurality of pixel circuits 11 provided on the resin film A.

In this sensor element 10, each of the pixel circuits 11 includes a photodiode (photoelectric conversion element) 11A and a thin-film transistor (TFT) 11B serving as a driver element for the photodiode 11A. By sensing light passing through the resin film A with each of the photodiodes 11A, the sensor element 10 can serve as an optical sensor element.

On the resin film A, a gate insulating film 21 is provided. The gate insulating film 21 is constituted of a single layer film including any one of a silicon oxide (SiO₂) film, a silicon oxynitride (SiON) film and a silicon nitride (SiN) film; or a laminated film including two of more of these films. On the gate insulating film 21, a first interlayer insulating film 12A is provided. The first interlayer insulating film 12 A is constituted of a silicon oxide film, a silicon nitride film or the like. This first interlayer insulating film 12A can also serve as a protective film (passivation film) to cover the top of the thin-film transistor 11B described below.

The photodiode 11A is formed on a selective region of the resin film A through the gate insulating film 21 and the first interlayer insulating film 12A. The photodiode 11A includes a lower electrode 24 formed on the first interlayer insulating film 12A, a n-type semiconductor layer 25N, an i-type semiconductor layer 25I, a p-type semiconductor layer 25P, an upper electrode 26 and a wiring layer 27. The lower electrode 24, the n-type semiconductor layer 25N, the i-type semiconductor layer 25I, the p-type semiconductor layer 25P, the upper electrode 26 and the wiring layer 27 are laminated from the side of the first interlayer insulating film 12A in this order.

The upper electrode 26 serves as an electrode for supplying, for example, a reference potential (bias potential) to a photoelectric conversion layer during a photoelectric conversion. The photoelectric conversion layer is constituted of the n-type semiconductor layer 25N, the i-type semiconductor layer 25I and the p-type semiconductor layer 25P. The upper electrode 26 is connected to the wiring layer serving as a power supply wiring for supplying the reference potential. This upper electrode 26 is constituted of a transparent conductive film of ITO (indium tin oxide) or the like.

The thin-film transistor 11B is constituted of, for example, a field effect transistor (FET). The thin-film transistor 11B includes a gate electrode 20, a gate insulating film 21, a semiconductor film 22, a source electrode 23S and a drain electrode 23D.

The gate electrode 20 is formed of titanium (Ti), Al, Mo, tungsten (W), chromium (Cr) or the like and formed on the resin film A. The gate insulating film 21 is formed on the gate electrode 20. The semiconductor layer 22 has a channel region and is formed on the gate insulating film 21. The source electrode 23S and the drain electrode 23D are formed on the semiconductor film 22. In this embodiment, the drain electrode 23D is connected to the lower electrode 24 of the photodiode and the source electrode 23S is connected to a relay electrode 28 of the sensor element 10.

Further, in the sensor element 10 of this embodiment, a second interlayer insulating film 12B, a first flattened film 13A, a protective film 14 and a second flattened film 13B are laminated on the photodiode 11A and the thin-film transistor 11B in this order. Further, an opening 3 is formed on the first flattened film 13A so as to correspond to the vicinity of the selective region on which the photodiode 11A is formed.

In the sensor element 10 having such a configuration, the light transmitting from outside into the sensor element 10 passes through the resin film A and reaches to the photodiodes 11A. As a result, it is possible to sensor the light transmitting from outside into the sensor element 10.

(Method of Manufacturing Organic EL Display Device 1 or Sensor Element 10)

The organic EL display device 1 having the configuration as described above or the sensor element 10 having the configuration as described above is manufactured by, for example, using the resin composition of the present invention as follows. That is, the organic EL display device 1 or the sensor element 10 can be manufactured by using the method of manufacturing the electronic device of the present invention.

FIG. 3 is a vertical sectional view to illustrate the method of manufacturing the organic electroluminescence display device shown in FIG. 1 or the sensor element shown in FIG. 2 (method of manufacturing the electronic device of the present invention). In the following description, the upper side in FIG. 3 will be referred to as “upper”, and the lower side in FIG. 3 will be referred to as “lower”.

First, description will be made on the method of manufacturing the organic electroluminescence display device 1 shown in FIG. 1.

[1] First, the substrate (substrate of the present invention) is prepared. The substrate (substrate of the present invention) includes a plate-like base member 500 having a first surface and a second surface opposite to the first surface; and the resin film A. In this step, the resin film (electronic element formation layer) A is provided at a side of the first surface of the base member 500.

[1-A] First, the base member 500 having the first surface and the second surface, and having light transparency is prepared.

For example, glass, a metal, silicone, a resin or the like is used as a constituent material for the base member 500. These materials may be used alone or in combination of two or more as appropriate.

[1-B] Next, the resin film A is formed on the first surface (one surface) of the base member 500. As a result, the substrate including the base member 500 and the resin film A (laminated composite material in FIG. 3) is obtained.

The resin composition of the present invention is used to form the resin film A. The resin composition of the present invention contains an aromatic polyamide and a solvent dissolving the aromatic polyamide. By using such a resin composition, the resin film (electronic element formation layer) A containing the aromatic polyamide is formed, wherein a total light transmittance of the resin film A in a wavelength of 355 nm is 10% or less.

Examples of the method of forming the resin film A include a method in which the resin composition (varnish) is supplied on the first surface of the base member 500 by using a die coat method as shown in FIG. 3(A), and thereafter the resin composition is dried and heated (referred to FIG. 3(B)).

In this regard, it is to be noted that a method of supplying the resin composition on the first surface of the base member 500 is not limited to the die coat method. Various kinds of liquid-phase film formation methods such as an ink jet method, a spin coat method, a bar coat method, a roll coat method, a wire bar coat method and a dip coat method can be used as such a method.

Further, as described above, the resin composition of the present invention contains the aromatic polyamide and the solvent dissolving the aromatic polyamide. By using such a resin composition, it is possible to obtain the resin film A containing the aromatic polyamide, wherein the total light transmittance of the resin film A in the wavelength of 355 nm is 10% or less. This resin composition of the present invention will be described later.

In one or plurality of embodiments of this disclosure, in terms of suppression of curvature deformation and/or enhancement of dimension stability, a heating treatment is carried out to the resin film A under the temperature in the range from approximately +40° C. of a boiling point of the solvent to approximately +100° C. of the boiling point of the solvent, more preferably in the range from approximately +60° C. of the boiling point of the solvent to approximately +80° C. of the boiling point of the solvent, even more preferably at approximately +70° C. of the boiling point of the solvent. In one or plurality of embodiments of this disclosure, in terms of suppression of curvature deformation and/or enhancement of dimension stability, the temperature of the heating treatment in this step [1-B] is in the range of approximately 200 to 250° C. In one or plurality of embodiments of this disclosure, in terms of suppression of curvature deformation and/or enhancement of dimension stability, a heating time (duration) in this step [1-B] is in the range of more than approximately 1 minute but less than approximately 30 minutes.

Further, this step [1-B], in which the resin film A is formed on the base member 500, may include a step of curing the resin film A after drying and heating the resin composition. A temperature of curing the resin film A depends on performance of a heating apparatus, but is preferably in the range of 220 to 420° C., more preferably in the range of 280 to 400° C., further more preferably in the range of 330 to 370° C., and even more preferably higher than 340° C. or in the range of 340 to 370° C. A time (duration) of curing the resin film A is preferably in the range of 5 to 300 minutes, and more preferably in the range of 30 to 240 minutes.

[2] Next, the thin-film transistors B are formed on the resin film A provided in the obtained substrate so as to correspond to pixels to be formed. Thereafter, the planarizing layer 301 is formed on the resin film A so as to cover each thin-film transistor B.

[2-A] First, each thin-film transistor B is formed on the resin film A.

[2-Aa] First, a conductive film is formed on the resin film A. Thereafter, the gate electrode 200 is formed by carrying out a patterning treatment to the conductive film.

The formation of the conductive film onto the resin film A can be performed by supplying a metal material such as aluminum, tantalum, molybdenum, titanium, tungsten and the like onto the resin film A with a sputter method and the like.

[2-Ab] Next, the gate insulating layer 201 is formed on the resin film A so as to cover the gate electrode 200.

This gate insulating layer 201 is formed with a plasma CVD method using, for example, TEOS (tetraethoxysilane), oxygen gas, nitrogen gas and the like as raw material gas (source gas). By using such a plasma CVD method, it is possible to form the gate insulating layer 201 constituted of an oxide silicon or a nitride silicon which is a main material of the gate insulating layer 201.

[2-Ac] Next, the conductive film is again formed on the gate insulating layer 201. Thereafter, the source electrode 202 and the drain electrode 204 are formed by carrying out the patterning treatment to the conductive film on the gate insulating layer 201.

The formation of the conductive film on the gate insulating layer 201 can be performed by using the same method as that described in the step [2-Aa].

[2-Ad] Next, the semiconductor layer 203 is formed in the channel region located between the source electrode 202 and the drain electrode 204.

This semiconductor layer 203 can be formed by a sputtering method under atmosphere containing oxygen (and nitrogen) using a metal target containing the metalloid element and/or the metal element included in the oxide semiconductor material described above.

[2-B] Next, the planarizing layer 301 is formed on the resin film A so as to cover the thin-film transistor B. Further, the conductive part 300 is formed to electrically connect the anode 302 and the drain electrode 204.

[2-Ba] First, the planarizing layer 301 is formed so as to cover the resin film A and the thin-film transistor B formed on the resin film A.

[2-Bb] Next, a contact hole is formed, and then the conduct part 300 is formed in the contact hole.

[3] Next, the light emitting devices (electron element) C are formed on each planarizing layer 301 so as to correspond to each thin-film transistor B.

[3-A] First, the anode (individual electrode) 302 is formed on the planarizing layer 301 so as to correspond to each conductive part 300.

[3-B] Next, the hole transport layer 303 is formed so as to cover the anode 302.

[3-C] Next, the emission layer 304 is formed so as to cover the hole transport layer 303.

[3-D] Next, the electron transport layer 305 is formed so as to cover the emission layer 304.

[3-E] Next, the cathode 306 is formed so as to cover the electron transport layer 305.

In this regard, each layer formed in the steps [3-A] to [3-E] can be formed by using a gas-phase film formation method such as a sputter method, a vacuum deposition method and a CVD method or a liquid-phase film formation method such as an ink jet method, a spin coat method and a casting method.

[4] Next, the sealing substrate 400 is prepared. Then, the light emitting devices C are sealed with the sealing substrate 400 by covering the cathode 306 of each light emitting device C with the sealing substrate (covering layer) 400. Namely the sealing substrate 400 is formed so as to cover each light emitting device C.

In this regard, the sealing with the sealing substrate 400 as described above can be performed by interposing an adhesive between the cathode 306 and the sealing substrate 400 and then drying the adhesive.

By carrying out the steps [1] to [4] as described above, the organic EL display device 1 including the resin film A, thin-film transistors B, the light emitting devices C and the sealing substrate 400 is formed on the base member 500 (referred to FIG. 3(C)).

[5] Next, the resin film A (electronic element formation layer) is irradiated with light from a side of the base member 500.

By doing so, the resin film A is peeled off from the first surface of the base member 500 in an interface between the base member 500 and the resin film A.

As a result, the organic EL display device (electronic device) 1 is separated from the base member 500 (referred to FIG. 3(D)).

The light to be irradiated to the resin film A is not particularly limited to a specific kind as long as the resin film A can be peeled off from the first surface of the base member 500 in the interface between the base member 500 and the resin film A by irradiating the resin film A with the light. The light is preferably laser light. By using the laser light, it is possible to reliably peel off the resin film A from the base member 500 in the interface between the base member 500 and the resin film A.

Further, examples of the laser light include an excimer laser of a pulse oscillator type or a continuous emission type, a carbon dioxide laser, a YAG laser and a YVO₄ laser.

By carrying out the steps [1] to [5] as described above, it is possible to obtain the organic electroluminescence display device 1 peeled off from the base member 500.

Next, description will be made on the method of manufacturing the sensor element shown in FIG. 3.

[1] First, in the same manner as the method of manufacturing the organic electroluminescence display device 1 shown in FIG. 1, the substrate (substrate of the present invention) including the base member 500 and the resin film (electronic element formation layer) A formed on the base member 500 is prepared. Since a step for forming the resin film A on the base member 500 is identical to that of the method of manufacturing the organic electroluminescence display device 1 described above, description to the step for forming the resin film A on the base member 500 is omitted here (referred to FIGS. 3(A) and 3(B)).

[2] Next, the sensor element 10 described above is formed on the resin film A provided in the obtained substrate. A method for forming the sensor element 10 on the resin film A is not particularly limited to a specific method. The formation of the sensor element 10 on the resin film A can be carried out with a known suitable method appropriately selected or modified for manufacturing a desired sensor element.

By carrying out the steps [1] to [2] as described above, the sensor element 10 including the resin film A, the pixel circuits 11 is formed on the base member 500 (referred to FIG. 3(C)).

[3] Next, the resin film (electronic element formation layer) A is irradiated with the light from the side of the base member 500 to peel off the sensor element (electronic device) 10 from the base member 500 (referred to FIG. 4(D)). Since a step for peeling off the sensor element from the base member 500 is identical to the above-mentioned step for peeling off the organic electroluminescence display device 1 from the base member 500, description to the step for peeling off the sensor element 10 from the base member 500 is omitted here.

By carrying out the steps [1] to [3] as described above, it is possible to obtain the sensor element 10 peeled off from the base member 500.

In the case where the resin film A has the light transparency in a wavelength width from a short wavelength to a long wavelength, the light irradiated from the side of the first surface of the base member 500 to the resin film A transmits through the resin film A, and then reaches the thin-film transistors B and the light emitting devices C provided in the organic EL display device 1. At this time, if the irradiated light contains the light having the short wavelength, the oxide semiconductor material included in the semiconductor layer 203 provided in each thin-film transistor B is altered or deteriorated due to the exposure to the light having the short wavelength. As a result, a problem in that adverse effects are given to switching property of the organic EL display device 1 occurs.

In the same manner, the light irradiated from the side of the first surface of the base member 500 to the resin film A transmits through the resin film A, and then reaches the photodiodes 11A and the thin-film transistors 11B provided in the sensor element 10. At this time, if the irradiated light contains the light having the short wavelength, oxide semiconductor materials included in the semiconductor layers 25N, 25I, 25P provided in each photodiode 11A and an oxide semiconductor material included in the semiconductor film 22 in each thin-film transistor 11B are altered or deteriorated due to the exposure to the light having the short wavelength. As a result, a problem in that adverse effects are given to switching property of the sensor element 10 occurs.

For the purpose of solving such a problem, in the present invention, the resin film A contains the aromatic polyamide and is constituted from a layer of which total light transmittance in the wavelength of 355 nm is 10% or less. This makes it possible to reliably suppress or prevent the light (in particular, the light having the short wavelength) irradiated from the side of the first surface of the base member 500 into the resin film A from transmitting through the resin film A. Therefore, it is possible to reliably prevent the adverse effects from being given to the switching property of the organic EL display device 1 or the switching property of the sensor element 10 due to the irradiation of the light.

As described above, the resin film A having the configuration as described above can be formed by using the resin composition of the present invention which contains the aromatic polyamide and the solvent dissolving the aromatic polyamide. Hereinafter, detailed description will be made on constituent materials for the resin composition of the present invention.

[Aromatic Polyamide]

The aromatic polyamide is used as a main material of the resin composition used for forming the resin film (electronic element formation layer) A. In order to set the total light transmittance of the resin film A in the wavelength of 355 nm to be 10% or less, the aromatic polyamide is contained in the resin composition.

Furthermore, by containing the aromatic polyamide in the resin composition, it is also possible to efficiently perform the peeling-off of the resin film A from the base member 500 in the interface between the base member 500 and the resin film A due to the irradiation of the light to the resin film A.

As described above, such an aromatic polyamide is not particularly limited to specific kind as long as it can set the total light transmittance of the resin film A in the wavelength of 355 nm to be 10% or less. For example, it is preferred that the aromatic polyamide has a main chemical structure thereof containing a naphthalene structure. By using the aromatic polyamide as the main material of the resin film A, it is possible to reliably set the total light transmittance of the formed resin film A to fall within the above range.

Further, it is preferred that the aromatic polyamide contains a carboxyl group bonding to a main chain of the aromatic polyamide. By using the aromatic polyamide containing the carboxyl group bonding to the main chain thereof, it is possible to improve solvent resistance of the formed resin film A, thereby expanding the range of choices for a liquid material used for forming the thin-film transistor B and the light emitting device C on the resin film A.

Furthermore, it is preferred that the aromatic polyamide is a wholly aromatic polyamide, namely the aromatic polyamide is constituted of only an aromatic skeleton. By using the wholly aromatic polyamide, it is possible to reliably set the total light transmittance of the formed resin film A to fall within the above range. In this regard, it is to be noted that the wholly aromatic polyamide refers to that all of amide bonds included in the main chain of the aromatic polyamide are bonded to each other through the aromatic group (aromatic ring) without bonding to each other through a chain or cyclic aliphatic group.

In view of the foregoing, it is preferred that the aromatic polyamide has a first repeating unit represented by the following general formula (I) and a second repeating unit represented by the following general formula (II):

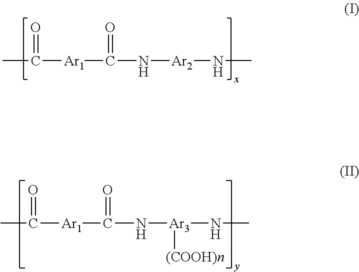

where x represents mol % of the first repeating unit, y represents mol % of the second repeating unit, n represents an integer of 1 to 4, Ar₁ is represented by the following general formula (III);

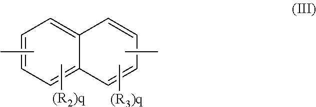

(where q=3 and each of R₂ and R₃ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them), Ar₂ is represented by the following general formula (IV) or (V);

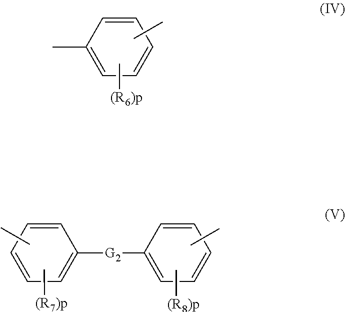

(where p=4, each of R₆, R₇ and R₈ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them, and G₂ is selected from the group consisting of a covalent binding, a CH₂ group, a C(CH₃)₂ group, a C(CF₃)₂ group, a C(CX₃)₂ group (X represents a halogen atom), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.)), and Ar₃ is represented by the following general formula (VI) or (VII);

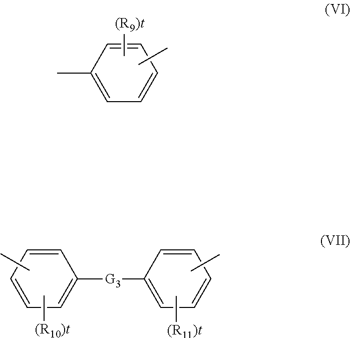

(where t=1 to 3, each of R₉, R₁₀ and R₁₁ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them, and G₃ is selected from the group consisting of a covalent binding, a CH₂ group, a C(CH₃)₂ group, a C(CF₃)₂ group, a C(CX₃)₂ group (X represents a halogen atom), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.)).

In one or plurality of embodiments of this disclosure, the general formulas (I) and (II) are selected so that the aromatic polyamide is soluble with respect to a polar solvent or a mixed solvent containing one or more polar solvents. In one or plurality of embodiments of this disclosure, x in the general formula (I) varies in the range of 90.0 to 99.99 mol %, and y in the general formula (II) varies in the range of 10.0 to 0.01 mol %. In one or plurality of embodiments of this disclosure, x in the general formula (I) varies in the range of 90.1 to 99.9 mol %, and y in the general formula (II) varies in the range of 9.9 to 0.1 mol %. In one or plurality of embodiments of this disclosure, x in the general formula (I) varies in the range of 90.0 to 99.0 mol %, and y in the general formula (II) varies in the range of 10.0 to 1.0 mol %. In one or plurality of embodiments of this disclosure, x in the general formula (I) varies in the range of 92.0 to 98.0 mol %, and y in the general formula (II) varies in the range of 8.0 to 2.0 mol %. In one or plurality of embodiments of this disclosure, the aromatic polyamide contains multiple repeat units represented with the general formulas (I) and (II) where Ar₁, Ar₂, and Ar₃ may be the same as or different from each other.

Further, a number average molecular weight (Mn) of the aromatic polyamide is preferably 6.0×10⁴ or more, more preferably 6.5×10⁴ or more, more preferably 7.0×10⁴ or more, further more preferably 7.5×10⁴ or more and even more preferably 8.0×10⁴ or more. Further, the number average molecular weight of the aromatic polyamide is preferably 1.0×10⁶ or less, more preferably 8.0×10⁵ or less, further more preferably 6.0×10⁵ or less, and even more preferably 4.0×10⁵ or less. By using the aromatic polyamide satisfying the above condition, it is possible for the resin film A to reliably provide a function as a foundation layer in the organic EL display device 1 or the sensor element 10. Further, it is possible to reliably set the total light transmittance of the resin film A to fall within the range described above.

In the present specification, the number average molecular weight (Mn) and a weight average molecular weight (Mw) of the polyamide are measured with a Gel Permeation Chromatography. Specifically, they are measured by using the method in the following Examples.

Further, molecular weight distribution of the aromatic polyamide (=Mw/Mn) is preferably 5.0 or less, more preferably 4.0 or less, more preferably 3.0 or less, further more preferably 2.8 or less, further more preferably 2.6 or less, and even more preferably 2.4 or less. Further, the molecular weight distribution of the aromatic polyamide is preferably 2.0 or more. By using the aromatic polyamide satisfying the above condition, it is possible for the resin film A to reliably provide the function as the foundation layer in the organic EL display device 1 or the sensor element 10. Further, it is possible to reliably set the total light transmittance of the resin film A to fall within the range described above.

It is preferred that the aromatic polyamide is obtained through a step of re-precipitating it after the aromatic polyamide is synthesized. By using the aromatic polyamide obtained through the step of re-precipitation, it is possible for the resin film A to reliably provide the function as the foundation layer in the organic EL display device 1 or the sensor element 10. Further, it is possible to reliably set the total light transmittance of the resin film A to fall within the range described above.

In one or plurality of embodiments of this disclosure, one or both of a terminal COOH group and a terminal NH₂ group of the aromatic polyamide are end-capped. The end-capping of the terminals is preferable from the point of view of enhancement of heat resistance property of the polyamide film (namely, resin film A). The terminals of the polyamide can be end-capped by either the reaction of polymerized polyamide with benzoyl chloride in the case of the terminal of polyamide is —NH₂, or the reaction of polymerized polyamide with aniline in the case of the terminal of polyamide is —COOH. However, the method of end-capping is not limited to this method.

[Inorganic Filler]

It is preferred that the resin composition contains an inorganic filler in addition to the aromatic polyamide. By using the resin composition containing the inorganic filler, it is possible to reduce a coefficient of thermal expansion of the resin film A.

This inorganic filler is not particularly limited to a specific kind, but is preferably constituted of a fiber or is preferably formed into a particle shape.

Further, a constituent material for the inorganic filler is not particularly limited to a specific material as long as it is an inorganic material. Examples of such a constituent material for the inorganic filler include a metal oxide such as silica, alumina and a titanium oxide; a mineral such as mica; glass; and a mixture of them. These materials may be used singly or in combination of two or more of them. In this regard, examples of a kind of glass include E glass, C glass, A glass, S glass, D glass, NE glass, T glass, low permittivity glass and high permittivity glass.

In the case where the inorganic filler is constituted of the fiber, an average fiber diameter of the fiber is preferably in the range of 1 to 1000 nm. By using the resin composition containing the inorganic filler having the above average fiber diameter, it is possible for the resin film A to reliably provide the function as the foundation layer in the organic EL display device 1 or the sensor element 10. Further, it is possible to reliably set the total light transmittance of the resin film A to fall within the range described above.

Here, the fiber may be formed of single fibers. The single fibers included therein are arranged without paralleling with each other and to be sufficiently spaced apart from each other so that a liquid precursor of a matrix resin enters among the single fibers. In this case, the average fiber diameter corresponds to an average diameter of the single fibers. Further, the fiber may constitute one line of thread in which a plurality of single fibers is bundled. In this case, the average fiber diameter is defined as an average value of a diameter of the one line of thread. Specifically, the average fiber diameter is measured by the method in the Examples. Further, from the point of view of improving the transparency of the film, the average fiber diameter of the fiber is preferably small. Further, a refractive index of the polyamide resin included in the resin composition (polyamide solution) and a refractive index of the inorganic filler are preferably close to each other. For example, in the case where a difference of refractive indexes of a material to be used as the fiber and the polyamide in the wavelength of 589 nm is 0.01 or less, it becomes possible to form a film having high transparency regardless of the fiber diameter. Further, examples of a method of measuring the average fiber diameter include a method of observing the fiber with an electronic microscope.

Further, in the case where the inorganic filler is formed into the particle shape, an average particle size of the particles is preferably in the range of 1 to 1000 nm. By using the resin composition containing the inorganic filler in the form of the particle shape having the above average particle size, it is possible for the resin film A to reliably provide the function as the foundation layer in the organic EL display device 1 or the sensor element 10. Further, it is possible to reliably set the total light transmittance of the resin film A to fall within the range described above.

Here, the average particle size of the particles refers to a diameter corresponding to an average projection circle. Specifically, the average particle size of the particles is measured by the method in the Examples.

A shape of each of the particles is not particularly limited to a specific shape. Examples of the shape include a spherical shape, a perfect spherical shape, a rod shape, a plate shape and a combined shape of them. By using the inorganic filler having such a shape, it is possible to reliably set the total light transmittance of the resin film A to fall within the range described above.

Further, the average particle size of the particles is preferably small. Further, the refractive index of the polyamide resin included in the resin composition (polyamide solution) and the refractive index of the inorganic filler are preferably close to each other. This makes it possible to further improve the transparency of the resin film A. For example, in the case where a difference of refractive indexes of the material to be used as the particles and the polyamide in the wavelength of 589 nm is 0.01 or less, it becomes possible to form the resin film A having high transparency regardless of the particle size. Further, examples of a method of measuring the average particle size include a method of measuring the average particle size with a particle size analyzer.

A ratio of the inorganic filler in a solid matter contained in the resin composition (polyamide solution) is not particularly limited to a specific value, but is preferably in the range of 1 to 50 volume %, more preferably in the range of 2 to 40 volume %, and even more preferably in the range of 3 to volume %. On the other hand, a ratio of the aromatic polyamide in the solid matter contained in the resin composition (polyamide solution) is not particularly limited to a specific value, but is preferably in the range of 50 to 99 volume %, more preferably in the range of 60 to 98 volume %, and even more preferably in the range of 70 to 97 volume %.

In this regard, it is to be noted that the “solid matter” refers to a component other than the solvent contained in the resin composition in this specification. A volume conversion of the solid matter, a volume conversion of the inorganic filler and/or a volume conversion of the polyamide can be calculated from each component usage at the time of preparing the polyamide solution. Alternatively, they can be also calculated by removing the solvent from the polyamide solution.

[Other Components]

Furthermore, the resin composition may contain an antioxidant, au ultraviolet absorbing agent, a dye, a pigment, a filler such as another inorganic filler and the like, if needed, in the degrees to which the function of the foundation layer in the organic EL display device 1 or the sensor element 10 is not impaired and the total light transmittance of the resin film A is set to fall within the range described above.

[Amount of Solid Matter]

A ratio of the solid matter contained in the resin composition is preferably 1 volume % or more, more preferably 2 volume % or more, and even more preferably 3 volume % or more. Further, the ratio of the solid matter contained in the resin composition is preferably 40 volume % or less, more preferably volume % or less, and even more preferably 20 volume % or less. By setting the ratio of the solid matter contained in the resin composition to fall within the above range, it is possible for the resin film A to reliably provide the function as the foundation layer in the organic EL display device 1 or the sensor element 10. Further, it is possible to reliably set the total light transmittance of the resin film A to fall within the range described above.

[Solvent]

One to be able to solve the aromatic polyamide is used as the solvent, which is used to prepare a varnish (liquid material) containing the resin composition.

In one or plurality of embodiments of this disclosure, in terms of enhancement of solubility of the aromatic polyamide to the solvent, the solvent is preferably a polar solvent or a mixed solvent containing one or more polar solvents. In one or plurality of embodiments of this disclosure, in terms of enhancement of solubility of the aromatic polyamide to the solvent and enhancement of the adhesion between the resin film A and the base member 500, the solvent is preferably cresol; N,N-dimethyl acetamide (DMAc); N-methyl-2-pyrrolidinone (NMP); dimethyl sulfoxide (DMSO); 1,3-dimethyl-imidazolidinone (DMI); N,N-dimethyl formamide (DMF); butyl cellosolve (BCS); γ-butyrolactone (GBL) or a mixed solvent containing at least one of cresol, N,N-dimethyl acetamide (DMAc), N-methyl-2-pyrrolidinone (NMP), dimethyl sulfoxide (DMSO), 1,3-dimethyl-imidazolidinone (DMI), N,N-dimethyl formamide (DMF), butyl cellosolve (BCS) and γ-butyrolactone (GBL); a combination thereof or a mixed solvent containing at least one of the polar solvent thereof.

[Method of Manufacturing Resin Composition]

The resin composition as described above can be manufactured by using, for example, a manufacturing method including the following steps (a) to (d).

Hereinafter, description will be made on a case where the resin composition contains the inorganic filler.

However, the resin composition of the present invention is not limited to a resin composition manufactured by using the following manufacturing method.

The step (a) is carried out for obtaining a mixture by dissolving at least one aromatic diamine in a solvent. The step (b) is carried out for obtaining free hydrochloric acid and a polyamide solution by reacting the at least one aromatic diamine with at least one aromatic dicarboxylic acid dichloride in the mixture. The step (c) is carried out for removing the free hydrochloric acid in the mixture by reaction with a trapping reagent. The step (d) is carried out for adding the inorganic filler to the mixture.

In one or more embodiments of the method for manufacturing the polyamide solution of this disclosure, examples of the aromatic dicarboxylic acid dichloride include compounds represented by the following general formula (VIII):

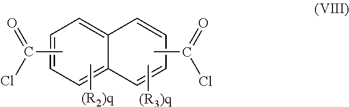

where q=3 and each of R₂ and R₃ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group and a combination of them.

Specifically, examples of the aromatic dicarboxylic acid dichloride as described above include the following compounds.

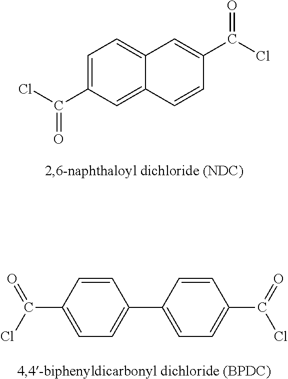 [SMILES: O=C(Cl)c1ccc2cc(C(=O)Cl)ccc2c1 ; O=C(Cl)c1ccc(-c2ccc(C(=O)Cl)cc2)cc1]

In one or more embodiments of the method for manufacturing the polyamide solution of this disclosure, examples of the aromatic diamine include compounds represented by the following general formulas (IX) to (XII):

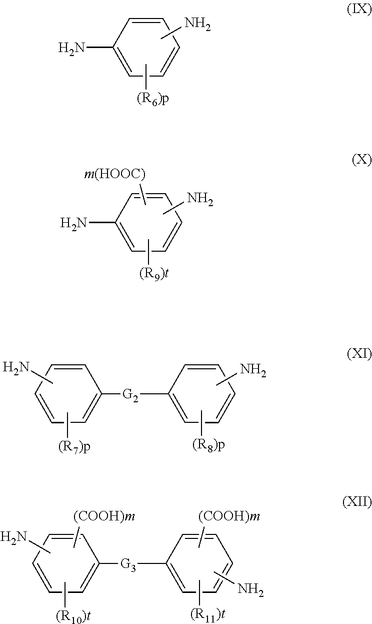

where p=4, m=1 or 2, and t=1 to 3, and where each of R₆, R₇, R₈, R₉, R₁₀, R₁₁ is selected from the group consisting of a hydrogen atom, a halogen atom (a fluorine atom, a chlorine atom, a bromine atom, and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group and combinations thereof. It is to be understood that each R₆ can be different, each R₇ can be different, each R₈ can be different, each R₉ can be different, each R₁₀ can be different, and each R₁₁ can be different. G₂ and G₃ are selected from the group consisting of a covalent bond; a CH₂ group; a C(CH₃)₂ group; a C(CF₃)₂ group; a C(CX₃)₂ group, wherein X is a halogen atom; a CO group; an O atom; an S atom; an SO₂ group; an Si(CH₃)₂ group; a 9,9-fluorene group; a substituted 9,9-fluorene group; and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.).

Specifically, examples of the aromatic diamine as described above include the following compounds.

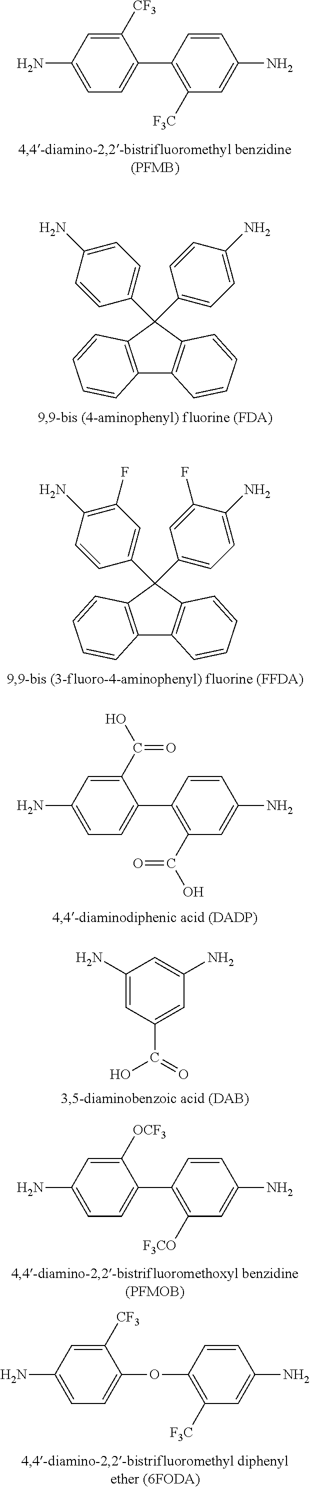

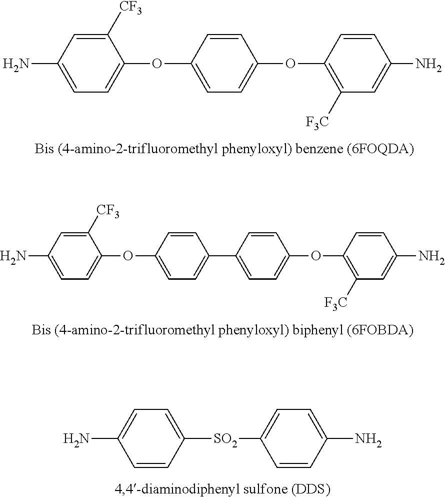

Regarding the diaminodiphenyl sulfone (DDS), the diaminodiphenyl sulfone may be 4,4′-diaminodiphenyl sulfone as expressed by the above formula, 3,3′-diaminodiphenyl sulfone or 2,2′-diaminodiphenyl sulfone.

In one or more embodiments of the method for manufacturing the polyamide solution of this disclosure, the polyamide is prepared via a condensation polymerization in a solvent, where hydrochloric acid generated in the reaction is trapped by a reagent such as propylene oxide (PrO).

In one or plurality of embodiments of this disclosure, in terms of use of the polyamide solution in the method, the reaction of hydrochloric acid with the trapping reagent yields a volatile product.

In one or plurality of embodiments of this disclosure, in terms of use of the polyamide solution in the method, the trapping reagent is propylene oxide. In one or plurality of embodiments of this disclosure, the trapping reagent is added to the mixture before or during the step (c). By adding the reagent before or during the step (c), it is possible to reduce a degree of viscosity and generation of condensation in the mixture after the step (c), and thereby, improving productivity of the polyamide solution. These effects become especially remarkable when the reagent is an organic reagent such as propylene oxide.

In one or plurality of embodiments of this disclosure, in terms of enhancement of heat resistance property of the resin film A, the method further includes a step of end-capping one or both of the terminal —COOH group and the terminal —NH₂ group of the polyamide. The terminals of the polyamide can be end-capped by either the reaction of polymerized polyamide with benzoyl chloride in the case where the terminal of polyamide is —NH₂, or the reaction of polymerized polyamide with aniline in the case where the terminal of polyamide is —COOH. However, the method of end-capping is not limited to this method.

In one or plurality of embodiments of this disclosure, in terms of use of the polyamide solution in the method, the polyamide is first isolated from the polyamide solution by re-precipitation and re-dissolution in a solvent prior to the addition of the inorganic filler.

A re-precipitation can be carried out by a known method. In one or plurality of embodiments of this disclosure, the re-precipitation can be carried out by precipitating the polyamide by adding it to, for example, methanol, ethanol, isopropyl alcohol or the like; washing the polyamide; and re-dissolving the polyamide to the solvent.

The solvent described above can be used as a solvent for producing the polyamide solution.

In one or plurality of embodiments of this disclosure, in terms of use of the polyamide solution in the method, the solution is produced so that the solution contains no inorganic salts.

By taking the steps as described above, the resin composition can be manufactured.

Further, the resin film A formed by using the resin composition obtained through the steps described above contains the aromatic polyamide. Thus, the total light transmittance of the resin film A in the wavelength of 355 nm can be preferably set to be 10% or less. In particular, the total light transmittance of the resin film A in the wavelength of 355 nm is preferably 5% or less, more preferably 3% or less, further more preferably 2% or less, and even more preferably 1% or less. By setting the total light transmittance of the resin film A in the wavelength of 355 nm to fall within the above range, it is possible to reliably suppress or prevent the light (in particular, the light having the short wavelength) from transmitting through the resin film A and then reaching the semiconductor layer 203.

Furthermore, a total light transmittance at wavelength of the resin film A in the wavelength of 400 nm is preferably set to be 70% or more, more preferably 75% or more, and even more preferably 90% or more. By setting the total light transmittance the resin film A in the wavelength of 400 nm to fall within the above range, it is possible for the light having the long wavelength to reliably transmit through the resin film A.

Furthermore, a retardation (Rth) of the resin film A in the wavelength of 400 nm in a thickness direction thereof is preferably 200.0 nm or less, more preferably 190.0 nm or less, further more preferably 180.0 nm or less, further more preferably 175.0 nm or less, and even more preferably 173.0 nm or less. In this regard, it is to be noted that the Rth of the resin film (polyamide film) A is obtained with a phase difference measurement device, specifically, is measured by using the method in the Examples.

Furthermore, a coefficient of thermal expansion (CTE) of the resin film A is preferably 100.0 ppm/K or less, more preferably 80 ppm/K or less, further more preferably 60 ppm/K or less, and even more preferably 40 ppm/K or less. In this regard, it is to be noted that the CTE of the resin film A is obtained with a thermal mechanical analyzer (TMA), specifically, is measured by using the method in the Examples.

By respectively setting the Rth and the CTE of the resin film A to fall within the above ranges, it is possible to reliably suppress or prevent warpage from occurring in the substrate including the base member 500 and the resin film A. Therefore, it is possible to improve a yield ratio of the organic EL display device 1 or the sensor element 10 obtained by using such a substrate.

In the case where the resin film A contains the inorganic filler, an amount of the inorganic filler contained in the resin film A is preferably in the range of 1 to 50 volume %, more preferably in the range of 2 to 40 volume %, and even more preferably in the range of 3 to 30 volume %, with respect to the volume of the resin film A. By adding the inorganic filler to the resin film A in the above amount, it is possible to easily set the Rth and the CTE of the resin film A to fall within the above ranges. In this regard, a volume conversion of the resin film A and/or a volume conversion of the inorganic filler can be respectively calculated from component usages at the time of preparing the resin composition, or they can be also obtained by measuring the volume of the resin film A.

Further, an average thickness of the resin film A is not particularly limited a specific value, but is preferably 50 μm or less, more preferably 30 μm or less, and even more preferably 20 μm or less. In addition, the average thickness is preferably 1 μm or more, more preferably 2 μm or more, and even more preferably 3 μm or more. By using the resin film A having the above average thickness, it is possible for the resin film A to reliably provide the function as the foundation layer in the organic EL display device 1 or the sensor element 10. Further, it is possible to reliably suppress or prevent cracks from generating in the resin film A.

Although the descriptions have been made on the resin composition, the substrate and the method of manufacturing the electronic device of the present invention based on the embodiments, the present invention is not limited thereto.

For example, in the resin composition and the substrate of the present invention, each component may be replaced with an arbitrary one capable of providing the same function. Alternatively, an arbitrary component may be added to them.

Further, in the method of manufacturing the electronic device of the present invention, one or more steps may be further added for the arbitrary purpose.

Further, in the above embodiments, the method of manufacturing the electronic device of the present invention is used to manufacture the organic EL display device 1 or the sensor element 10 including the photodiode. However, the method of manufacturing the electronic device of the present invention is not limited thereto. For example, the method of the manufacturing the electronic device of the present invention may be used to not only manufacture other display devices such as a crystal display device, but also manufacture various kinds of electronic devices such as an input device including a sensor element as the electronic element, a display device including a display element as the electronic element, an optical device including an optical element as the electronic element and a solar cell including a photoelectric conversion element as the electronic element. Further, examples of the electronic elements include not only the thin-film transistor and the photodiode but also light emitting devices such as an organic EL device, a photoelectric conversion element and a piezoelectric element.

### EXAMPLES

Hereinafter, the present invention will be described based on specific examples in detail.

### 1. Preparation of Resin Composition and Formation of Resin Film

### Example 1

### Preparation of Resin Composition

<1> PFMB (3.042 g, 0.0095 mol), DAB (0.0761 g, 0.0005 mol) and DMAc (30 ml) were added to a 250 ml three necked round bottom flask, which is equipped with a mechanical stirrer, a nitrogen inlet and outlet, in order to obtain a solution.

<2> After the PFMB and DAB were completely dissolved in the solution, PrO (1.4 g, 0.024 mol) was added to the solution. Then, the solution was cooled to 0° C.

<3> Under stirring, IPC (Isophthaloyl dichloride, 1.909 g, 0.0090 mol) and NDC (0.253 g, 0.001 mol) were added to the solution, and then the flask wall was washed with DMAc (1.5 ml).

<4> After two hours, benzoyl chloride (0.032 g, 0.23 mmol) was added to the solution and stirred for more two hours.

[Formation of Resin Film (Polyamide Film)]

A resin film was formed on a glass substrate by using the prepared resin composition.

That is, first, the resin composition was applied onto a flat glass substrate (10 cm×10 cm, “EAGLE XG” produced by Corning Inc., U.S.A.) with a spin coat method.

Next, the resin composition was dried at a temperature of 60° C. for 30 minutes or more to obtain a film. Thereafter, the temperature was raised from 60° C. to 350° C. The film was subjected to a curing treatment by keeping the temperature of 350° C. for 30 minutes under vacuum atmosphere or inert atmosphere. By doing so, a resin film was formed on the glass substrate.

In this regard, a thickness of the resin film was about 10.2 μm.

### Example 2

A resin composition of the Example 2 was prepared in the same manner as the Example 1, except that the combination of IPC and NDC was changed to a combination of IPC (1.697 g, 0.00800 mol), TPC (Terephthaloyl dichloride, 0.212 g, 0.00100 mol) and NDC (0.253 g, 0.00100 mol) as the dichloride component used in the step <3>. Thereafter, a resin film of the Example 2 was formed on the glass substrate by using the prepared resin composition in the same manner as the Example 1.

In this regard, a thickness of the obtained resin film was about 10.0 μm.

### Example 3

A resin composition of the Example 3 was prepared in the same manner as the Example 1, except that the combination of IPC and NDC was changed to a combination of IPC (1.485 g, 0.00700 mol), TPC (0.212 g, 0.00100 mol) and NDC (0.506 g, 0.00200 mol) as the dichloride component used in the step <3>. Thereafter, a resin film of the Example 3 was formed on the glass substrate by using the prepared resin composition in the same manner as the Example 1.

In this regard, a thickness of the obtained resin film was about 10.6 μm.

### Example 4

A resin composition of the Example 4 was prepared in the same manner as the Example 1, except that the combination of IPC and NDC was changed to a combination of IPC (1.697 g, 0.00800 mol) and NDC (0.506 g, 0.00200 mol) as the dichloride component used in the step <3>. Thereafter, a resin film of the Example 4 was formed on the glass substrate by using the resin composition in the same manner as the Example 1.

In this regard, a thickness of the obtained resin film was about 10.1 μm.

### Example 5

A resin composition of the Example 5 was prepared in the same manner as the Example 1, except that the combination of IPC and NDC was changed to a combination of IPC (0.636 g, 0.00300 mol) and NDC (1.772 g, 0.00700 mol) as the dichloride component used in the step <3>. Thereafter, a resin film of the Example 5 was formed on the glass substrate by using the resin composition in the same manner as the Example 1.

In this regard, a thickness of the obtained resin film was about 10.5 μm.

### Example 6

A resin composition of the Example 6 was prepared in the same manner as the Example 1, except that the combination of IPC and NDC was changed to only NDC (2.531 g, 0.00100 mol) as the dichloride component used in the step <3>. Thereafter, a resin film of the Example 6 was formed on the glass substrate by using the resin composition in the same manner as the Example 1.

In this regard, a thickness of the obtained resin film was about 10.3 μm.

### Comparative Example

A resin composition of the Comparative Example was prepared in the same manner as the Example 1, except that the combination of IPC and NDC was changed to a combination of IPC (1.909 g, 0.00900 mol) and TPC (0.212 g, 0.00100 mol) as the dichloride component used in the step <3>. Thereafter, a resin film of the Comparative Example was formed on the glass substrate by using the resin composition in the same manner as the Example 1.

In this regard, a thickness of the obtained resin film was about 10.0 μm.

### 2. Evaluation

The resin film obtained from the resin composition of each of the Examples and the Comparative Example was evaluated in accordance with the following methods.

[Total Light transmittance (Wavelengths of 355 nm and 400 nm)]

The total light transmittances of the resin film in the wavelengths of 355 nm and 400 nm were obtained by using a spectral photometer (N-670, produced by JASCO).

The thickness and the total light transmittances of the resin film obtained from the resin composition obtained in each of the Examples and the Comparative Example as described above were shown in Table 1 below as results. Then, the results were evaluated.

TABLE 1

| | | | | | | Polymer | | | | |
|---|---|---|---|---|---|---|---|---|---|---|
| | Composition | | | | | | | | Total light | |
| | Diamine | | Dichloride | | | Curing | | | transmittance | |
| | PFMB | DAB | IPC | TPC | NDC | Temp. | Time | Thickness | 355 | 400 |
| | mol % | mol % | mol % | mol % | mol % | ° C. | min | um | % | % |
| Example 1 | 95 | 5 | 90 | 0 | 10 | 350 | 30 | 10.2 | 6.3 | 83.3 |
| Example 2 | 95 | 5 | 80 | 10 | 10 | 350 | 30 | 10.0 | 4.9 | 83.6 |
| Example 3 | 95 | 5 | 70 | 10 | 20 | 350 | 30 | 10.6 | 1.3 | 83.1 |
| Example 4 | 95 | 5 | 80 | 0 | 20 | 350 | 30 | 10.1 | 1.5 | 82.8 |
| Example 5 | 95 | 5 | 30 | 0 | 70 | 350 | 30 | 10.5 | 0.8 | 78.9 |
| Example 6 | 95 | 5 | 0 | 0 | 100 | 350 | 30 | 10.3 | 0.3 | 77.0 |
| Comparative | 95 | 5 | 90 | 10 | 0 | 350 | 30 | 10.0 | 37.6 | 83.7 |
| Example | | | | | | | | | | |

As shown in Table 1, in each of the resin films obtained in the Examples, excellent results were obtained, that the total light transmittance of the resin film at the wavelength of 355 nm was 10% or less and the total light transmittance of the resin film at the wavelength of 400 nm was 70% or more.

In contrast, sufficient results were not obtained in the resin film in the Comparative Example.

What is claimed is:

1. A resin composition comprising:
an aromatic polyamide; and
a solvent dissolving the aromatic polyamide,
wherein the resin composition is used to form a layer, and a total light transmittance of the layer in a wavelength of 355 nm is 10% or less.

2. The resin composition according to claim 1, wherein the aromatic polyamide contains a naphthalene structure.

3. The resin composition according to claim 1, wherein the aromatic polyamide contains a carboxyl group.

4. The resin composition according to claim 1, wherein the aromatic polyamide is a wholly aromatic polyamide.

5. The resin composition according to claim 1, wherein the aromatic polyamide has a first repeating unit represented by the following general formula (I) and a second repeating unit represented by the following general formula (II): 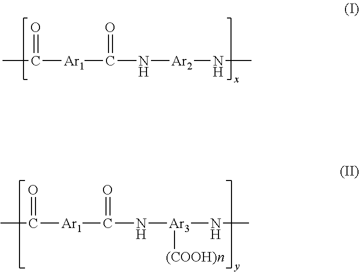
where x represents mol % of the first repeating unit, y represents mol % of the second repeating unit, n represents an integer of 1 to 4, Ar₁ is represented by the following general formula (III); 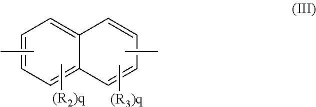
(where q=3 and each of R₂ and R₃ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them), Ar₂ is represented by the following general formula (IV) or (V); 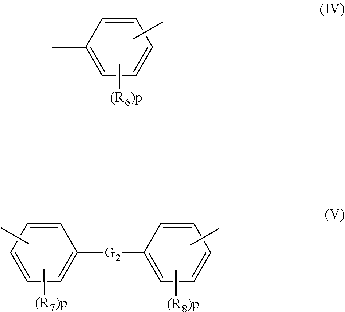
(where p=4, each of R₆, R₇ and R₈ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them, and G₂ is selected from the group consisting of a covalent binding, a CH₂ group, a C(CH₃)₂ group, a C(CF₃)₂ group, a C(CX₃)₂ group (X represents a halogen atom), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.)), and Ar₃ is represented by the following general formula (VI) or (VII); 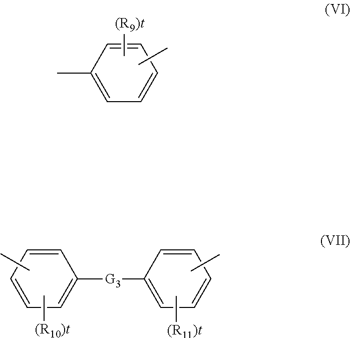
(where t=1 to 3, each of R₉, R₁₀ and R₁₁ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them, and G₃ is selected from the group consisting of a covalent binding, a CH₂ group, a C(CH₃)₂ group, a C(CF₃)₂ group, a C(CX₃)₂ group (X represents a halogen atom), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.)).

6. The resin composition according to claim 1, wherein at least one end of the aromatic polyamide is end-capped.

7. The resin composition according to claim 1, wherein the resin composition further contains an inorganic filler.

8. A substrate used for forming an electronic element thereon, comprising:
a plate-like base member having a first surface and a second surface opposite to the first surface;
an electronic element formation layer provided at a side of the first surface of the base member and configured to be capable of forming the electronic element on the electronic element formation layer; and
wherein the electronic element formation layer contains an aromatic polyamide and a total light transmittance of the electronic element formation layer in a wavelength of 355 nm is 10% or less.

9. The substrate according to claim 8, wherein a coefficient of thermal expansion (CTE) of the electronic element formation layer is 100 ppm/K or less.

10. The substrate according to claim 8, wherein an average thickness of the electronic element formation layer is in the range of 1 to 50 μm.

11. A method of manufacturing an electronic device, comprising:
preparing a substrate, the substrate including,
a plate-like base member having a first surface and a second surface opposite to the first surface, and
an electronic element formation layer provided at a side of the first surface of the base member,
wherein the electronic element formation layer is used to form an electronic element on the electronic element formation layer and contains an aromatic polyamide, and
wherein a total light transmittance of the electronic element formation layer in a wavelength of 355 nm is 10% or less;
forming the electronic element on a surface of the electronic element formation layer opposite to the base member;
forming a cover layer so as to cover the electronic element;
irradiating the electronic element formation layer with light to thereby peel off the electronic element formation layer from the base member in an interface between the base member and the electronic element formation layer; and
separating the electronic device including the electronic element, the cover layer and the electronic element formation layer from the base member.

12. The method according to claim 11, wherein a coefficient of thermal expansion (CTE) of the electronic element formation layer is 100 ppm/K or less.

13. The method according to claim 11, wherein an average thickness of the electronic element formation layer is in the range of 1 to 50 μm.

14. The method according to claim 11, wherein the aromatic polyamide has a first repeating unit represented by the following general formula (I) and a second repeating unit represented by the following general formula (II): 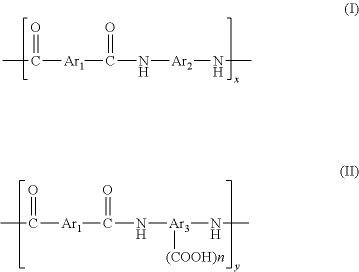
where x represents mol % of the first repeating unit, y represents mol % of the second repeating unit, n represents an integer of 1 to 4, Ar₁ is represented by the following general formula (III); 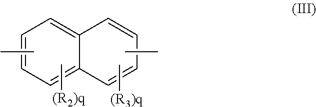
(where q=3 and each of R₂ and R₃ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them), Ar₂ is represented by the following general formula (IV) or (V); 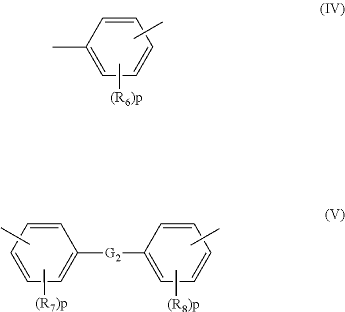
(where p=4, each of R₆, R₇ and R₈ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them, and G₂ is selected from the group consisting of a covalent binding, a CH₂ group, a C(CH₃)₂ group, a C(CF₃)₂ group, a C(CX₃)₂ group (X represents a halogen atom), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.)), and Ar₃ is represented by the following general formula (VI) or (VII); 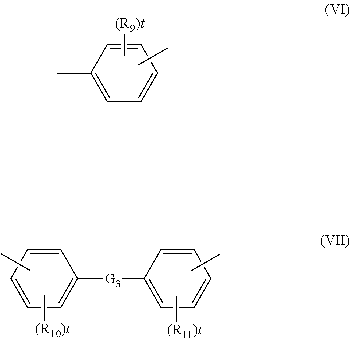
(where t=1 to 3, each of R₉, R₁₀ and R₁₁ is selected from the group consisting of a hydrogen atom, a halogen atom (a fluorine atom, a chlorine atom, a bromine atom and an iodine atom), an alkyl group, a substituted alkyl group such as a halogenated alkyl group, a nitro group, a cyano group, a thioalkyl group, an alkoxy group, a substituted alkoxy group such as a halogenated alkoxy group, an aryl group, a substituted aryl group such as a halogenated aryl group, an alkyl ester group, a substituted alkyl ester group, and a combination of them, and G₃ is selected from the group consisting of a covalent binding, a CH₂ group, a C(CH₃)₂ group, a C(CF₃)₂ group, a C(CX₃)₂ group (X represents a halogen atom), a CO group, an oxygen atom, a sulfur atom, an SO₂ group, an Si(CH₃)₂ group, a 9,9-fluorene group, a substituted 9,9-fluorene group and an OZO group (Z represents an aryl group or substituted aryl group such as a phenyl group, a biphenyl group, a perfluorobiphenyl group, a 9,9-bisphenyl fluorene group and a substituted 9,9-bisphenyl fluorene group.)).
